(19) United States
(12) Patent Application Publication
(10) Pub. No.: US 2026/0280531 A1
(43) Pub. Date: Sep. 17, 2026

(54) Pulse Width Actuated Switch Filter System

(71) Applicant: Stephen R. Capasso, II, Tucson, AZ (US)

(72) Inventor: Stephen R. Capasso, II, Tucson, AZ (US)

(21) Appl. No.: 19/342,243

(22) Filed: Sep. 26, 2025

Related U.S. Application Data
(60) Provisional application No. 63/770,540, filed on Mar. 12, 2025.

(51) Int. Cl. H03H 11/04; H03K 3/017; H03K 3/037

(52) U.S. Cl. CPC H03H 11/04; H03K 3/017; H03K 3/037

(57) ABSTRACT

A pulse width actuated switch filter system and method for pulse width actuated switch filtering provides enhanced sensitivity through adaptive filtering based on input pulse signal width characteristics. The system comprises multiple processing channels, each configured to detect specific pulse widths and automatically activate corresponding optimized low-pass filters. Each processing channel includes an operational amplifier buffer functioning as a low noise amplifier to maintain signal to-noise ratio, a D-type flip-flop that converts amplified and conditioned signals into steady-state digital DC output signals, and a TTL-compatible transistor-based buffer driver. The system integrates a switching matrix routing signals to appropriate low-pass filters based on detected pulse widths, with each low-pass filter specifically designed to provide optimal sensitivity enhancement for its corresponding pulse duration. This architecture overcomes conventional convolution processing limitations, achieving sensitivity improvements for enhanced radar target detection in challenging electromagnetic environments while maintaining signal processing integrity through selective filter activation.

### (B) REFERENCE TO RELATED APPLICATIONS

This application claims priority to and the benefit of U.S. Provisional Patent Application Ser. No. 63/770,540, filed Mar. 12, 2025, the entire disclosure of which is incorporated herein by reference.

### (C) STATEMENT OF FEDERALLY SPONSORED RESEARCH

Not Applicable

### (D) JOINT RESEARCH AGREEMENT

Not Applicable

### (E) REFERENCE TO A “SEQUENCE LISTING,” A TABLE, OR A COMPUTER PROGRAM

Not Applicable

### (F) STATEMENT REGARDING PRIOR DISCLOSURES BY AN INVENTOR OR JOINT INVENTOR

Not Applicable

### (G) BRIEF DESCRIPTION OF THE DRAWINGS

FIG. 1 shows a block diagram of the Pulse Width Actuated Switch Filter System (100), detecting input pulse signals and outputting filtered output signals

FIG. 2 shows a flow chart of the steps for pulse width actuated switch filtering, detecting input pulse signals and outputting filtered output signals

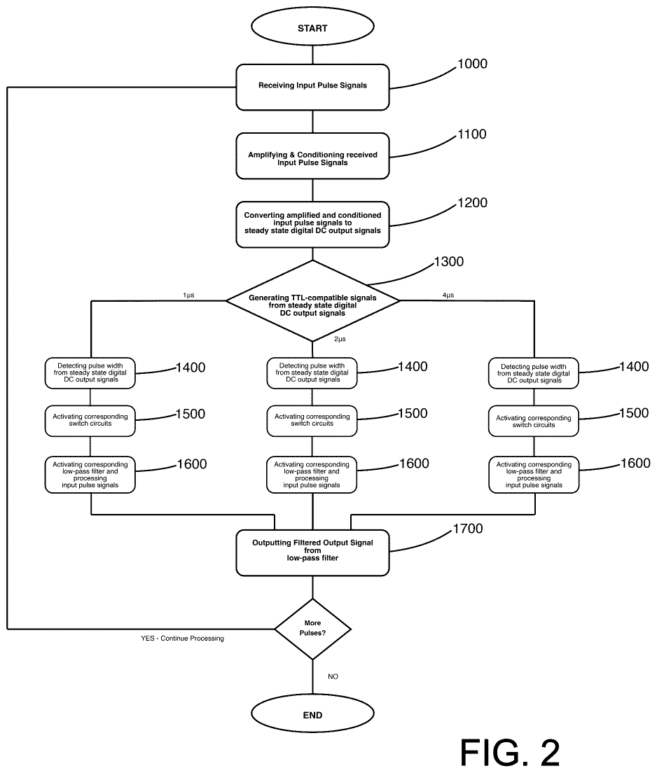

FIG. 3 shows an electronic schematic of the Pulse Width Actuated Switch Filter System (100), detecting input pulse signals and outputting filtered output signals

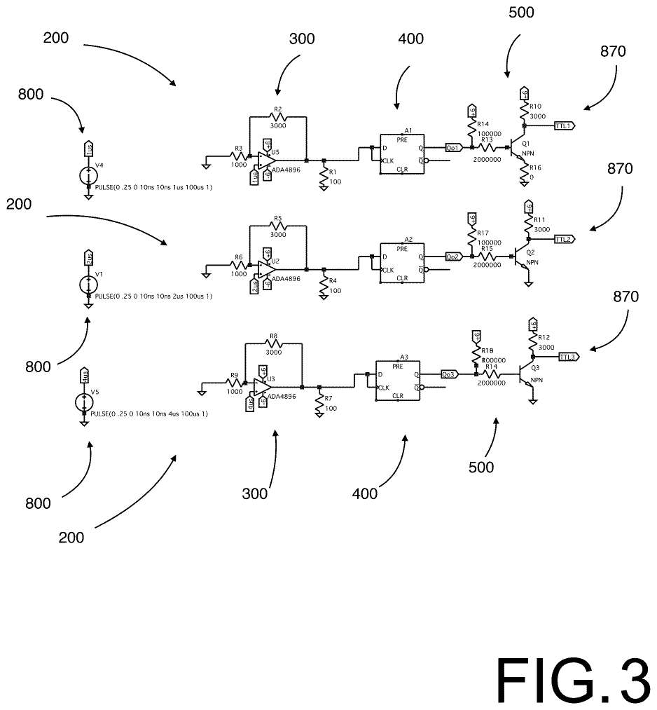

FIG. 4 shows Table 1, describing the variables and initial values in the equation

FIG. 5 shows Table 2, demonstrating Bᵥ (kHz) and BW (kHz) as a function of Pulse Width (μs)

FIG. 6 shows Table 3, demonstrating Sₘₐₓ (dBm) Sₓ(dBm) and TSS (dBm) as a function of Pulse Width (μs)

### (H) BACKGROUND OF THE INVENTION

### (H) 1 Field of the Invention

This invention relates to the field of radar signal processing systems, particularly adaptive filtering technologies that enhance target detection sensitivity and signal-to-noise ratio performance in electromagnetic sensing applications. The system is specifically applicable to radar installations requiring optimized signal conditioning for multiple pulse width configurations, including military surveillance systems, air traffic control networks, automotive collision avoidance sensors, and maritime navigation radar equipment.

### (H) 2 Introduction

A pulse width actuated switch filter operates by using the duration or width of incoming pulse signals as the primary criterion for switching or filtering decisions. This device monitors the temporal characteristics of electrical pulses and activates switching mechanisms only when pulses meet specific width thresholds or fall within predetermined time windows. The filter essentially acts as a temporal gate, allowing signals through or triggering responses based on how long each pulse remains active. This approach enables precise control over signal processing by distinguishing between pulses of different durations, effectively filtering out unwanted short-duration noise spikes or excessively long signals that may indicate system malfunctions or interference.

The utility of pulse width actuated switch filters spans numerous applications where signal integrity and precise timing control are paramount. In digital communication systems, these filters help maintain data integrity by ensuring only properly formatted pulses with correct timing characteristics are processed, thereby reducing transmission errors. Industrial control systems benefit from this technology by using pulse width as a safety mechanism—for instance, machinery might only respond to control signals that maintain specific pulse durations, preventing accidental activation from electrical noise or brief contact bounces. In radar and sonar applications, pulse width filtering enables better target discrimination and range accuracy by processing only returns that match the transmitted pulse characteristics. In power electronics, these filters can protect sensitive components by blocking pulses that are too short (indicating potential spikes) or too long (suggesting potential overload conditions).

### (H) 3 Usage of a Pulse Width Actuated Filter for Radar Applications

A pulse width defined radar utilizing a pulse width actuated switch filter assembly represents a sophisticated approach to radar signal processing that offers enhanced precision and filtering capabilities. This technology leverages the controlled timing of pulse widths to create more accurate target detection and range measurement systems. By incorporating a switch filter assembly that responds to specific pulse width parameters, the system can effectively discriminate between different types of signals and reduce unwanted interference or noise. This level of signal refinement is particularly valuable in applications requiring high-resolution radar performance, such as precision navigation, target tracking, or obstacle detection in complex electromagnetic environments.

The practical applications of this pulse width-controlled radar system extend across multiple industries and scenarios where reliable distance measurement and object detection are critical. In automotive applications, such systems could enhance autonomous vehicle sensor arrays by providing more accurate detection of nearby objects and better differentiation between static obstacles and moving vehicles. Military and aerospace applications benefit from the improved signal-to-noise ratio and enhanced target discrimination capabilities, allowing for more effective surveillance and tracking operations. Additionally, the technology shows promise in maritime navigation, air traffic control, and industrial automation where precise ranging and the ability to filter out environmental clutter are essential for safe and efficient operations.

### (H) 4 Issue

In radar signal processing applications, the convolution process, while providing fundamental signal enhancement through matched filtering and correlation techniques, proves insufficient to achieve the substantial sensitivity gains required for detecting weak targets or improving signal-to noise ratios in challenging electromagnetic environments. The inherent limitations of convolution-based processing become particularly evident when attempting to extract low-amplitude return signals from background noise or when operating in conditions with significant interference. While convolution effectively correlates transmitted and received waveforms to identify potential targets, the sensitivity improvements it provides often fall short of the performance thresholds needed for reliable detection of distant, small, or low-reflectivity objects that are critical in modern radar applications.

### (H) 5 Solution Approach

To address these sensitivity limitations, the radar system requires additional filtering mechanisms that act as sensitivity amplifiers, specifically designed to provide incremental “boost” factors that scale with pulse width characteristics. As the pulse width is systematically doubled in successive processing stages, each doubling interval demands a corresponding enhancement in filtering sensitivity to maintain optimal target detection capabilities. This approach recognizes that longer pulse widths inherently carry more energy and should theoretically provide better signal-to-noise ratios, but conventional processing methods fail to fully exploit this relationship. The additional filtering stages must therefore be calibrated to extract maximum benefit from each pulse width increment, creating a cascading effect where sensitivity improvements compound with each doubling cycle. This multi-stage filtering architecture ensures that the radar system can adaptively optimize its detection performance based on the specific pulse width parameters being employed, ultimately achieving the sensitivity levels necessary for reliable operation across diverse target scenarios and environmental conditions.

### (H) 6 Glossary

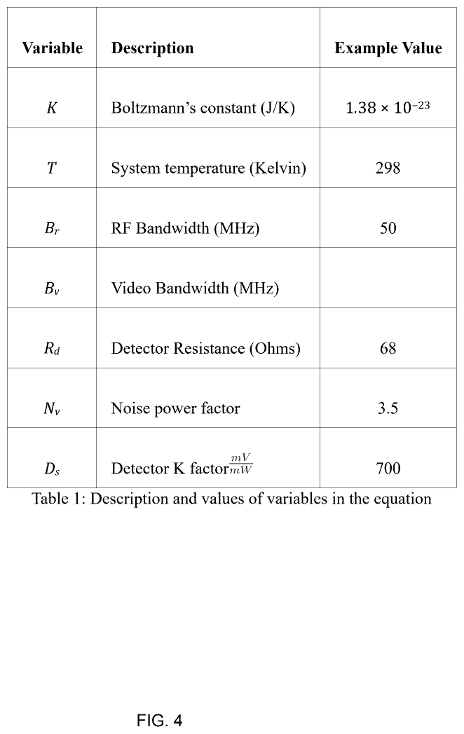

FIG. 4 shows Table 1, describing the variables and given values for the equation.

### (H) 7 Theoretical Underpinnings

Let's begin by calculating MFS_TSSeq for the various pulse widths of interest taking account their specific BWs. We need to analyze and agree upon the best approximation for each pulse width video BW. Various approaches have been put forth over the years such as:

$$BW = \frac{1}{τ} ( where τ is the pulse width ) Hz \qquad ( 1 )$$

Another is the relationship between response time of a pulse to calculate the BW where the expression

$$BW = \frac{\text{.35}}{risetime} Hz \qquad ( 2 )$$

Now according to my initial premise that THE RESPONSE TIME DEFAULTS TO THE PULSE WIDTH, due to convolution of two rectangular pulses, we can then state:

$$BW = \frac{\text{.35}}{pulsewidth} Hz \qquad ( 3 )$$

So for a 1 us, 2 us, 4 us pulse widths, we have:

$${BW}_{1 μ s} = \frac{\text{.35}}{1 μs} 350 kHz \qquad ( 4 )$$

$${BW}_{2 μ s} = \frac{\text{.35}}{2 μs} 175 kHz \qquad ( 5 )$$

$${BW}_{4 μ s} = \frac{\text{.35}}{4 μs} 87.5 kHz \qquad ( 6 )$$

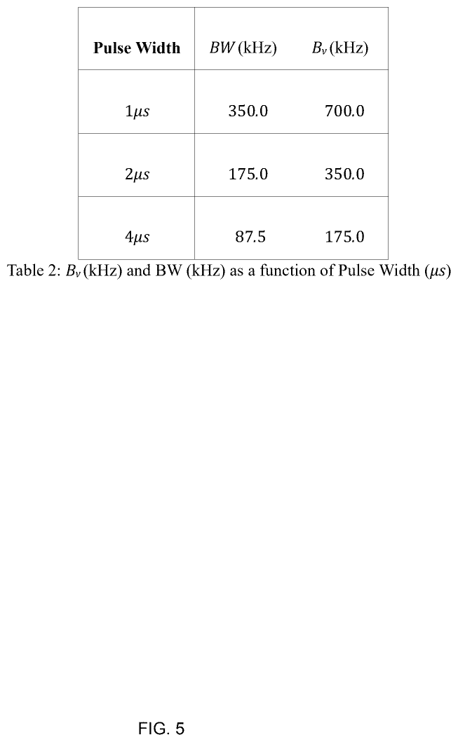

One other contribution is a consequence of the convolution process which states the two convolved pulses yields Bᵥ that is the product of the individual pulse widths G1 and G2 or G1×G2 which sums the individual BWs. FIG. 5 shows Table 2, demonstrating Bᵥ (kHz) and BW (kHz) as a function of Pulse Width (μs)

Let's go with these for now so we can get some revised Sensitivity results. Going back to my initial TSS calculation method we need two essential parameter results.
Sₘₐₓ, the effective noise power at the amplifier input;
Sₓ, the normal threshold sensitivity of a square law detector where the pulse power equals the noise power.

### Recall:

$${S}_{max} = 114 + 1 + 10 log ( \sqrt{2 {B}_{r} {B}_{v} + {( {B}_{v} )}^{2} )} \qquad ( 7 )$$

$${S}_{x} = 10 log ( \frac{( \sqrt{( 4 {KTB}_{v} {R}_{d} {N}_{v} )}}{Ds} ) \qquad ( 8 )$$

Varying only Bᵥ for each pulse width yields:

$$\begin{matrix}{S}_{max 1 μ s} = - 114 + 1 + 10 log ( \sqrt{2 ( 50 ) ( 0.7 ) + {( 0.7 )}^{2}} ) \\ = ( - 114 + 1 + 18.4 ) \\ = - 94.6 dBm\end{matrix} \qquad ( 9 )$$

$$\begin{matrix}{S}_{max 2 μ s} = - 114 + 1 + 10 log ( \sqrt{2 ( 50 ) ( 0.35 ) + {( 0.35 )}^{2}} ) \\ = ( - 114 + 1 + 15.46 ) \\ = - 97.54 dBm\end{matrix} \qquad ( 10 )$$

$$\begin{matrix}{S}_{max 4 μ s} = - 114 + 1 + 10 log ( \sqrt{2 ( 50 ) ( 0.175 ) + {( 0.175 )}^{2}} ) \\ = [ 114 + 1 + 12.4 ] \\ = - 100.6 dBm\end{matrix} \qquad ( 11 )$$

Similarly for Sₓ, adding conversion factors:

$$( 12 )$$

$${S}_{x} = 10 log ( \frac{( \sqrt{( 4 {KTB}_{v} {R}_{d} {N}_{v} )}}{Ds} ) 1000 \frac{mV}{V}$$

$$( 13 )$$

$$\begin{matrix}{S}_{x 1 μ s} = 10 log ( \frac{( \sqrt{( 4 ( 1.38 \times {10}^{- 23} ) ( 298 ) ( 0.7 \times {10}^{6} ) ( 68 ) ( 3.5 ) )}}{700} ) 1000 \frac{mV}{V} \\ = 10 log ( \frac{( \sqrt{2.74 \times {10}^{- 12}}}{700} ) 1000 \frac{mV}{V} \\ = - 56.26 dBm\end{matrix}$$

$$( 14 )$$

$$\begin{matrix}{S}_{x 2 μ s} = 10 log ( \frac{( \sqrt{( 4 ( 1.38 \times {10}^{- 23} ) ( 298 ) ( 0.7 \times {10}^{6} ) ( 68 ) ( 3.5 ) )}}{700} ) 1000 \frac{mV}{V} \\ = 10 log ( \frac{( \sqrt{1.37 \times {10}^{- 12}}}{700} ) 1000 \frac{mV}{V} \\ = - 57.77 dBm\end{matrix}$$

$$( 15 )$$

$$\begin{matrix}{S}_{x 4 μ s} = 10 log ( \frac{( \sqrt{4 ( 1.38 \times {10}^{- 23} ) ( 298 ) ( 0.175 \times {10}^{6} ) ( 68 ) ( 3.5 ) )}}{700} ) 1000 \frac{mV}{V} \\ = 10 log ( \frac{( \sqrt{6.85 \times {10}^{- 13}}}{700} ) 1000 \frac{mV}{V} \\ = - 59.27 dBm\end{matrix}$$

Finally the resultant MFS_TSSeq can now be calculated:

$$\begin{matrix}{TSS}_{1 μ s} = ( {S}_{max 1 μ s} + 10 log ( 2.5 + 0.5 ) ) \\ = ( - 94.6 + 4 + 0.5 ) \\ = - 90.1 dBm\end{matrix} \qquad ( 16 )$$

$$\begin{matrix}{TSS}_{2 μ s} = ( {S}_{max 2 μ s} + 10 log ( 2.5 + 0.5 ) ) \\ = ( - 97.54 + 4 + 0.5 ) \\ = - 93.04 dBm\end{matrix} \qquad ( 17 )$$

$$\begin{matrix}{TSS}_{4 μ s} = ( {S}_{max 4 μ s} + 10 log ( 2.5 + 0.5 ) ) \\ = ( - 100.6 + 4 + 0.5 ) \\ = - 96.1 dBm\end{matrix} \qquad ( 18 )$$

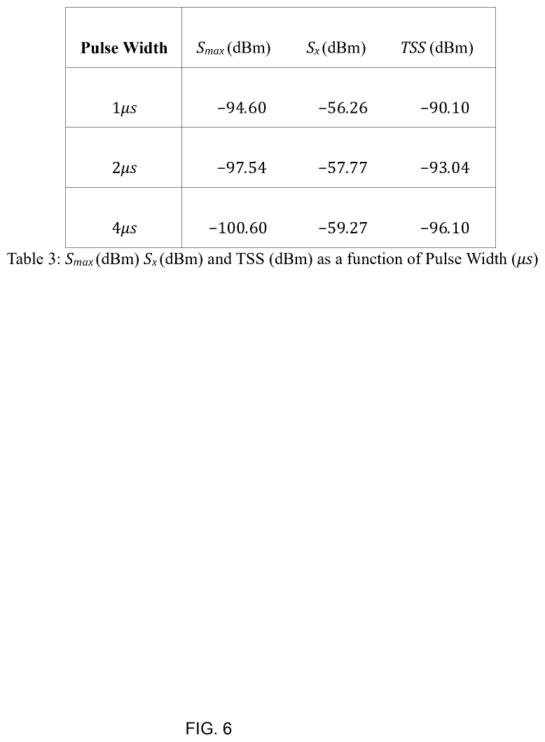

It's now clear for each pulse width doubling the Matched Filter Sensitivity MFS_TSSeq increases by 3 dB. Quadrupling the pulse width yields a 6 dB increase in Sensitivity allowing for a Radar distance doubling. FIG. 6 shows Table 3, demonstrating Sₘₐₓ(dBm) Sₓ(dBm) and TSS (dBm) as a function of Pulse Width (μs)

### (I) DETAILED DESCRIPTION OF THE INVENTION

### (I) 1 System Overview and Architecture

The pulse width actuated switch filter system (100) is designed as a n-processing channel (200) adaptive filtering architecture that automatically selects and activates an appropriate lowpass filter (610) based on the width of input pulse signals (800), where n is the number of processing channels (200) within the architecture. This system addresses the critical requirement for dynamic filter selection in radar applications where different pulse widths (e.g. three pulse widths: 1 μs, 2 μs, and 4 μs) require correspondingly optimized filtering characteristics to maximize signal processing effectiveness. The system operates on the principle that each distinct pulse width should be processed through its dedicated low-pass filter (e.g. LPF1, LPF2, and LPF3 respectively) to achieve optimal signal conditioning and noise reduction tailored to that specific temporal characteristic.

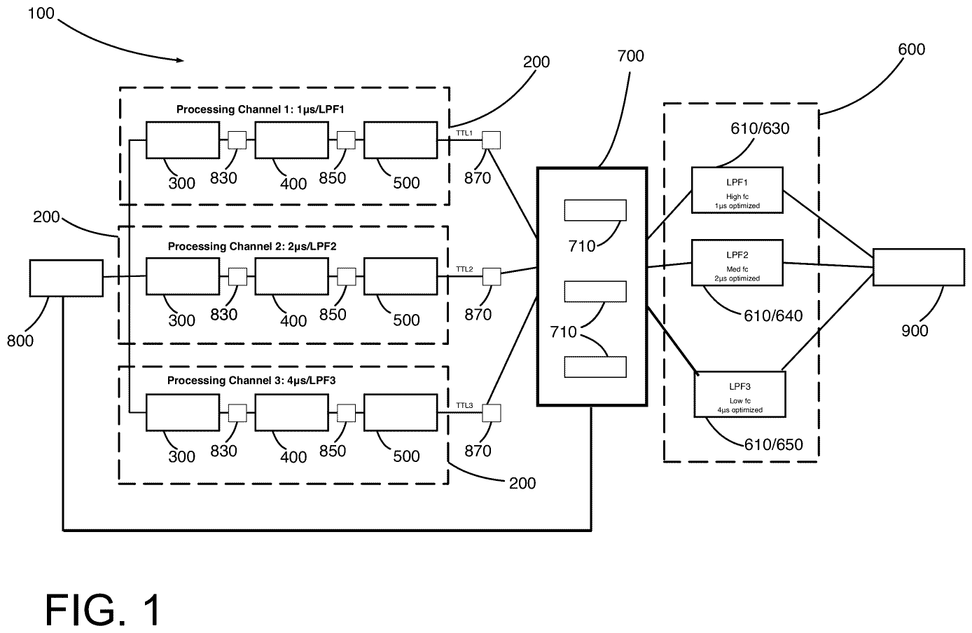

The pulse width actuated switch filter system (100) comprises a plurality of processing channels (200), a filter switching matrix (700), and a low-pass filter bank (600). FIG. 1 shows a block diagram of the Pulse Width Actuated Switch Filter System (100), detecting input pulse signals and outputting filtered output signals

### (I) 2 Signal Amplification and Conditioning Stage

Each processing channel (200) comprises an operational amplifier buffer (300), a D type flip-flop (400), and a transistor-based buffer driver (500).

The initial stage of each processing channel (200) incorporates an operational amplifier configured as a unity-gain buffer, functioning as a Low Noise Amplifier (LNA)—the “operational amplifier buffer” (300). This critical component serves multiple purposes within the system architecture. Once the processing channels (200) receive input pulse signals (1000), the operational amplifier buffer (300) amplifies and conditions the input pulse signals (1100), outputting amplified and conditioned signals (830).

In this signal amplification and conditioning stage (1100), the operational amplifier buffer (300) establishes and maintains an adequate signal-to-noise ratio (SNR) by amplifying the input pulse signals (800) while introducing minimal additional noise to the signal path. The operational amplifier buffer (300) provides high input impedance to prevent loading effects on the preceding circuitry and ensures signal integrity throughout the processing chain. Additionally, this signal conditioning and amplification stage (1100) normalizes the input pulse signals (800) and provides the necessary drive capability for subsequent processing stages, while its low-noise characteristics preserve the delicate balance between signal strength and noise floor that is essential for sensitive applications, such as radar.

### (I) 3 Digital State Conversion and Timing Control

Following the signal conditioning and amplification stage (1100), each processing channel (200) employs a D-type flip-flop (400) that performs the crucial function of converting (1200) the amplified and conditioned signals (830) into steady state digital DC output signals (850). This conversion process (1200) is fundamental to the actuated switch filter system's (100) operation, as it transforms the temporal information contained in the pulse width into steady state digital DC output signals (850) that can reliably control downstream switching circuits (710) within a switching matrix (700). The D-type flip-flop (400) captures the pulse width information at its input and maintains this state as a constant DC level at its output, effectively creating a memory element that preserves the pulse width detection event. This steady-state output eliminates timing uncertainties and provides steady state digital DC output signals (850) that persist long enough to ensure reliable activation of the associated filter switching circuitry.

### (I) 4 Output Driver and Interface Circuitry

The final stage of each processing channel (200) consists of a transistor-based buffer driver (500) specifically designed for TTL (Transistor-Transistor Logic) compatibility. This transistor-based buffer driver (500) stage takes the steady state digital DC output signals (850) from the D flip-flop (400) and generates robust TTL-compatible control signals (870) (e.g. TTL1, TTL2, or TTL3) capable of driving the switch circuits (710) with adequate current and voltage levels (1300). The transistor-based buffer driver (500) provides the necessary power amplification and signal conditioning to ensure reliable operation of the downstream switch circuits (710) that control the actual low-pass filters (610). These TTL-compatible control signals (870) serve as the control signals that activate the appropriate actual low-pass filters (610), creating a direct relationship between detected pulse width from the input pulse signals (800) and low-pass filter (600) activation.

### (I) 5 Integrated System Operation and Filter Selection

The complete system operates through parallel processing channels (200), where each of the n pulse width detection circuits (e.g. 3 parallel processing channels (200): 1 μs/LPF1, 2 μs/LPF2, and 4 μs/LPF3) functions simultaneously to monitor incoming input pulse signals (800). When a pulse (800) of specific width is detected (1400), only the corresponding processing channel (200) activates its TTL-compatible signals (870). This TTL-compatible signals (870) actuates a corresponding switch circuit (1500); when the corresponding switch circuit (710) is actuated, it creates a path from the input pulse signals (800) to the corresponding low-pass filter (1600), activating the corresponding low-pass filter (610). This selective activation ensures that each input pulse signals (800) with a discrete pulse width characteristic is processed through its optimally matched low-pass filter (610), providing the sensitivity boost required for that particular pulse width characteristic. The actuated switch filter system's (100) architecture guarantees mutual exclusivity in filter selection, preventing multiple filters from being simultaneously active and maintaining signal processing integrity. This coordinated operation between pulse width detection and filter selection creates an adaptive filtering system that automatically optimizes processing parameters based on the temporal characteristics of incoming radar signals, ultimately achieving the enhanced sensitivity performance required for effective radar operation across multiple pulse width scenarios.

### (I) 6 Filter Switching Matrix and Control Architecture

The switching matrix (700) forms the critical interface between the TTL-compatible control signals (870) and the low-pass filter selection mechanism, functioning as an electronically controlled routing matrix that ensures precise filter activation based on detected pulse width characteristics. switch circuit assembly (700) comprises a plurality of switch circuits (710), corresponding to a particular processing channel (200).

The switching matrix (700) comprises a plurality of switch circuits (700). The plurality of switch circuits (700) Each switch circuit (710) consists of high-speed analog switches, typically implemented using CMOS transmission gates or PIN diode configurations, that provide low insertion loss and minimal signal distortion during the switching process. The switch circuit (710) are designed to handle the full dynamic range of signals while maintaining isolation between inactive filter paths to prevent cross-coupling and signal leakage. The switching matrix (700) incorporates fail-safe logic to ensure that only one filter path can be active at any given time, preventing simultaneous activation of multiple low-pass filters (610) that could compromise signal processing integrity. Additionally, the switch circuits (710) include transient suppression and debouncing mechanisms to eliminate switching artifacts and ensure clean transitions between filter states, while maintaining the high-speed switching capability necessary for real-time radar signal processing applications.

### (I) 7 Adaptive Low-Pass Filter Bank Design and Characteristics

The low-pass filter bank (600) comprises n distinct filter circuits (610)—e.g. three filter circuits: LPF1 (630), LPF2 (640), and LPF3 (650)—each filter circuit (610) is specifically designed and optimized to complement its corresponding pulse width characteristics associated with a specific processing channel (200) and provide maximum sensitivity enhancement for radar signal processing. The low-pass filter bank (600) outputs filtered output signals (900).

In a three low-pass filter circuit configuration, we can label the three filter circuits (610): LPF1 (630), LPF2 (640), and LPF3 (650). For example, LPF1 (630) can be associated with 1 μs pulse widths, and features a higher cutoff frequency designed to preserve the fast-rising edges and spectral content necessary for short-duration pulse analysis, while providing sufficient noise reduction for weak signal detection. LPF2 (640), optimized for 2 μs pulses, incorporates a moderate cutoff frequency that balances noise reduction with signal fidelity, offering enhanced sensitivity for medium-duration pulse processing. LPF3 (640), designed for 4 μs pulse widths, employs the lowest cutoff frequency to maximize noise suppression and sensitivity gain, taking advantage of the longer pulse duration to achieve superior signal-to-noise ratios. Each filter circuit (610) utilizes active filter topologies with precision operational amplifiers to ensure consistent performance characteristics, temperature stability, and minimal phase distortion. The filter designs incorporate programmable gain stages that provide the cascading sensitivity “boost” factors, with each filter delivering progressively higher sensitivity enhancement that scales appropriately with the increased pulse width, thereby achieving the desired sensitivity multiplication effect that conventional convolution processing alone cannot provide.

1. A pulse width actuated switch filter system detecting input pulse signals, comprising:
(a) a plurality of processing channels, each processing channel comprising:
(i) an operational amplifier buffer configured to amplify and condition input pulse signals inputs while maintaining signal-to-noise ratio into amplified and conditioned signals;
(ii) a D-type flip-flop coupled to the operational amplifier buffer, the D-type flip-flop configured to convert the amplified and conditioned signals into steady-state digital DC output signals; and
(iii) a transistor-based buffer driver coupled to the D-type flip-flop output, the transistor buffer driver configured to generate TTL-compatible control signals from the steady state digital DC output signals as an output;
(b) a filter switching matrix, the filter switching matrix comprising:
(i) a plurality of switches;
(ii) where each switch is operationally connected the corresponding low-pass filter;
(iii) where each switch is operationally connected the corresponding processing channel;
(c) a low-pass filter bank, the low-pass filter bank comprising:
(i) a plurality of low-pass filters;
(ii) where each low-pass filter is operationally connected to the corresponding switch from the filter switching matrix;
(d) where each processing channel is configured to detect a discrete pulse width from the input pulse signals and to output corresponding TTL-compatible control signals,
(e) wherein the TTL-compatible control signals from each processing channel actuate respective switch circuits to selectively activate the corresponding low-pass filters based on detected pulse widths,
(i) wherein the input pulse signals are processed through the activated low-pass filter and the activated low-pass filter outputs filtered output signals.

2. The pulse width actuated switch filter system of claim 1,
(a) wherein the plurality of processing channels comprises exactly three processing channels, and
(b) wherein the corresponding low-pass filters comprise a first low-pass filter, a second lowpass filter, and a third low-pass filter.

3. The pulse width actuated switch filter system of claim 2,
(a) wherein the processing channels are configured to detect pulse widths of one microsecond, two microseconds, and four microseconds respectively.

4. The pulse width actuated switch filter system of claim 1,
(a) wherein the operational amplifier buffer in each processing channel is configured as a unity gain low noise amplifier that provides high input impedance and establishes adequate signal to-noise ratio for subsequent signal processing stages.

5. The pulse width actuated switch filter system of claim 1,
(a) wherein the D-type flip-flop in each processing channel captures pulse width information and maintains the captured state as a constant DC output level, thereby creating stable control signals that persist to ensure reliable activation of the associated filter switching circuitry.

6. The pulse width actuated switch filter system of claim 1,
(a) wherein the pulse width actuated switch filter system is integrated into a radar signal processing application, and
(b) wherein the selective activation of low-pass filters provides sensitivity enhancement that scales with pulse width characteristics to improve target detection capabilities.

7. A method for pulse width actuated switch filtering comprising:
(a) receiving input pulse signals at a plurality of processing channels, each processing channel configured to detect a specific pulse width;
(b) amplifying and conditioning the input pulse signals in each processing channel using an operational amplifier buffer while maintaining signal-to-noise ratio;
(c) converting the amplified and conditioned signals in each processing channel to steady-state DC output signals using a D-type flip-flop;
(d) generating TTL-compatible control signals in each processing channel from the steady-state DC output signals using a transistor-based buffer driver; and
(e) actuating respective switch circuits based on the TTL-compatible control signals and selectively activating corresponding low-pass filters by wherein each low-pass filter is activated only when its corresponding specific pulse width is detected;
(f) processing the input pulse signals through the selected activated low-pass filter;
(g) outputting a filtered output signals from the selected low-pass filter based on the input pulse signal.

8. The method for pulse width actuated switch filtering of claim 7,
(a) wherein the receiving input pulse signals comprises processing input pulse signals through exactly three processing channels configured to detect pulse widths of one microsecond, two microseconds, and four microseconds respectively; and
(b) herein selectively activating corresponding low-pass filters comprises activating a first lowpass filter, a second low-pass filter, or a third low-pass filter based on the detected pulse width from the input pulse signal.

9. The method for pulse width actuated switch filtering of claim 7,
(a) wherein amplifying and conditioning the input pulse signals comprises configuring the operational amplifier buffer as a unity-gain low noise amplifier that provides high input impedance and establishes adequate signal-to-noise ratio for reliable pulse width detection and subsequent low-pass filter activation.

10. The method for pulse width actuated switch filtering of claim 7,
(a) wherein converting rectangular input pulses to steady-state DC output signals comprises capturing pulse width information at the D-type flip-flop input and maintaining the captured state as a constant DC level output, thereby eliminating timing uncertainties and providing stable control signals for filter switching operations.

11. The method for pulse width actuated switch filtering of claim 7, further comprising:
(a) integrating the pulse width actuated switch filtering into radar signal processing operations; and
(b) achieving sensitivity enhancement that scales with detected pulse width characteristics to improve radar target detection capabilities through the selective activation of optimally matched low-pass filters.
